(19) United States
(12) Patent Application Publication
(10) Pub. No.: US 2026/0231718 A1
(43) Pub. Date: Aug. 6, 2026

(54) FLASH IRRADIATION APPARATUS

(71) Applicant: Ushio Denki Kabushiki Kaisha, Tokyo (JP)

(72) Inventor: Masayuki KONISHI, Tokyo (JP)

(73) Assignee: Ushio Denki Kabushiki Kaisha, Tokyo (JP)

(21) Appl. No.: 19/363,529

(22) Filed: Oct. 20, 2025

(30) Foreign Application Priority Data
Feb. 6, 2025 (JP) 2025-018429

(51) Int. Cl. H01L 21/67; H05B 1/02; H05B 3/00

(52) U.S. Cl. CPC H10P 72/0436; H05B 1/0233; H05B 3/0047; H05B 2203/035

(57) ABSTRACT

Provided is a flash irradiation apparatus suitable for heat treatment in a shorter time. The flash irradiation apparatus includes: a flash discharge lamp that generates a flash by discharge: a lighting circuit that includes a capacitor, a first switching element, a first diode, and a resistive element; a second switching element; and a controller that controls energization and non-energization of the first switching element and the second switching element. The controller executes first control to switch the second switching element from a non-energized state to an energized state, second control to switch the first switching element from the non-energized state to the energized state after executing the first control, and third control to switch the second switching element from the energized state to the non-energized state after executing the second control.

### CROSS-REFERENCE TO RELATED APPLICATION

The present invention claims the benefit of priority to Japanese Patent Application 2025-018429 with the Japanese Patent Office, the entire contents of which are incorporated herein by reference in its entirety.

### BACKGROUND OF THE INVENTION

### Field of the Invention

The present invention relates to a flash irradiation apparatus.

### Description of the Related Art

Conventionally, flash irradiation apparatuses have been used for heat treatment of semiconductor substrates and heat treatment in manufacturing processes in printable electronics and other fields. In recent years in particular, with the miniaturization of semiconductor processes, a method of instantaneous heat treatment using a flash irradiation apparatus has attracted attention as a method for activating implanted impurities while suppressing diffusion caused by prolonged heating.

Therefore, the present applicant has been developing a flash irradiation apparatus equipped with a flash discharge lamp (also referred to as a “flash lamp”) suitable for a semiconductor wafer heating treatment apparatus, and has developed, for example, a flash irradiation apparatus as described in Patent Document 1 below.

### Prior Art Document

### Patent Document

Patent Document 1: JP-A-2009-164080

### SUMMARY OF THE INVENTION

Further improvement has been intensively studied for a flash irradiation apparatus as described above as an indispensable apparatus for performing short-time heat treatment or the like on a semiconductor substrate. Recently, especially with the background that further miniaturization of semiconductor processes is under study, there has been a demand for a flash irradiation apparatus capable of further reducing the thermal history of a workpiece.

In view of the above issues, an object of the present invention is to provide a flash irradiation apparatus suitable for heat treatment in a shorter time.

A flash irradiation apparatus according to the present invention includes: a flash discharge lamp that generates a flash by discharge; a lighting circuit including a capacitor that has a first terminal connected to an anode of the flash discharge lamp and stores electric charge to be supplied to the flash discharge lamp, a first switching element that switches between energization and non-energization of a connection between a cathode of the flash discharge lamp and a second terminal of the capacitor, a first diode having a cathode terminal connected to the first terminal of the capacitor and an anode terminal connected to the cathode of the flash discharge lamp, and a resistive element having a first terminal connected to the cathode of the flash discharge lamp; a second switching element that switches between energization and non-energization of a connection between the second terminal of the resistive element and the second terminal of the capacitor; and a controller that controls switching between energization and non-energization of the first switching element and the second switching element. The controller executes first control to switch the second switching element from a non-energized state to an energized state, second control to switch the first switching element from the non-energized state to the energized state after executing the first control, and third control to switch the second switching element from the energized state to the non-energized state after executing the second control.

In the present specification, the term “connected” is used with the intention to include not only a configuration of direct connection but also a configuration of electrical connection via series-connected circuit elements, wiring, or the like.

In order to perform treatment on a workpiece in a shorter time, the present inventor considered executing control in which, at the time of completion of necessary flash irradiation, a switching element is switched from the energized state to the non-energized state to forcibly stop the flash irradiation.

Here, the flash irradiation apparatus described in Patent Literature 1 is equipped with a resistive element connected in parallel with a switching element. The resistive element is mounted to generate, near the tube axis of the light-emitting tube of the flash discharge lamp, a discharge (hereinafter possibly referred to as “main discharge”) that generates a flash for performing heating treatment on the workpiece.

The resistive element connected in parallel with the switching element is an element for generating an extremely weak current between the electrodes of the flash discharge lamp, compared to the main discharge, after a trigger voltage is applied to a trigger member and before the main discharge is generated. Note that the weak current as described above may be referred to as a shimmer current, a state in which the shimmer current flows may be referred to as shimmer discharge, and the resistive element as described above may be referred to as a shimmer resistor.

The shimmer current contributes to stable lighting of the flash discharge lamp and to extension of the lifespan of the flash discharge lamp, thereby playing an essential role in the flash irradiation apparatus.

Therefore, the present inventor conducted a trial experiment using a flash irradiation apparatus provided with a lighting circuit including a shimmer resistor, to switch a switching element from the energized state to the non-energized state at the time of completion of necessary flash irradiation. In the course of conducting the trial experiment, the present inventor found that the shimmer resistor had a shortened lifespan.

In the case of the operation as described above, at the time of switching of the switching element from the energized state to the non-energized state, a large amount of electric charge remains in the capacitor in which electric charge for the main discharge is stored. Then, the electric charge remaining in the capacitor is consumed by the shimmer resistor. That is, a part of the electric charge that would conventionally be consumed for lighting the flash discharge lamp is consumed in the shimmer resistor. In particular, the more an attempt is made to reduce the flash generation time, the greater the total amount of electric charge consumed by the shimmer resistor.

The present inventor, having noticed the above phenomenon, attempted to implement a configuration in which a switching element (second switching element) is mounted to cut off a discharge path to which the shimmer resistor is connected.

The present inventor intensively studied the above configuration and found that the following phenomenon occurs. After both the switching element (first switching element), which switches the main discharge path between energization and non-energization, and the second switching element are switched to the non-energized state, electric charge from the capacitor flows into the cathode side of the flash discharge lamp due to the influence of a parasitic inductor element or the like present in a cable or various members.

At this time, when both the first switching element and the second switching element are in the non-energized state, there is no destination for energy of an inductance element, and the potential may become extremely high relative to other nodes. When such a potential is generated, an extremely high voltage is applied between terminals of each switching element, which may cause damage or destruction of each switching element.

The present inventor has found that the above problem can be solved by mounting a diode (first diode) having a cathode terminal connected to the first terminal of the capacitor and an anode terminal connected to the cathode of the flash discharge lamp, to regenerate the energy of the inductance element.

As described above, the present inventor has invented the flash irradiation apparatus having the above configuration. As described above, according to the flash irradiation apparatus having the above configuration, in the flash irradiation apparatus having the function of generating a shimmer current, even when the control to switch the switching element from the energized state to the non-energized state is executed at the time of completion of the necessary flash irradiation, a circuit element constituting the lighting circuit is less likely to be damaged or destroyed. That is, the flash irradiation apparatus capable of performing heat treatment on a workpiece in a shorter time is implemented by combining the operational effects described above.

When the second switching element is not provided, when the charging operation of the capacitor in the next cycle starts in a state where the shimmer current flows after the main discharge, it is assumed that the charging operation is not completed during a predetermined cycle. The reason for this is as follows: since the path to which the shimmer resistor is connected is always in the energized state, while electric charge is stored in the capacitor, the electric charge stored in the capacitor is gradually discharged via the shimmer resistor.

That is, bringing the second switching element into the non-energized state after the main light emission enables operation in a predetermined cycle, because all charging current from a charger to the capacitor flows to the capacitor.

The flash irradiation apparatus may further include a plurality of the lighting circuits, and the second switching element may be connected to the plurality of the lighting circuits.

The second switching element may be connected to all of the plurality of lighting circuits, or may be connected to each of the group of lighting circuits. In the flash irradiation apparatus, a plurality of flash discharge lamps are mounted, and a lighting circuit corresponding to each of the flash discharge lamps or corresponding to some flash discharge lamp groups is often mounted. The second switching element can be shared by a plurality of lighting circuits because it is sufficient that the second switching element allows a current to flow so as to maintain the discharge that occurs in the light-emitting tube of the flash discharge lamp.

Here, although the resistive elements are connected in series, several kV, which is the same voltage as that of the first switching element, is applied to the second switching element, and the second switching element is therefore assumed to be an extremely large element having an insulation distance similar to that of the first switching element. When the resistive element is short-circuited due to a single failure, the current becomes on the order of several hundred A to several kA, which is similar to that of the first switching element, and the second switching element is assumed to be an extremely large element so as to withstand such a current. Then, when the second switching element is mounted on each of the plurality of lighting circuits, the entire flash irradiation apparatus becomes large.

Therefore, as in the above configuration, the second switching element is shared by the plurality of lighting circuits, thereby enabling a reduction in the size of the entire flash irradiation apparatus. In particular, the greater the number of flash discharge lamps mounted, the more the flash irradiation apparatus can be reduced in size. Note that the flash irradiation apparatus may constitute a circuit unit in which one second switching element is connected to a plurality of lighting circuits, and may include a plurality of such circuit units. With this configuration as well, a reduction in the size of the entire flash irradiation apparatus can be achieved.

Furthermore, in the flash irradiation apparatus, each of the plurality of the lighting circuits may include a second diode having an anode terminal connected to the cathode side of the flash discharge lamp and a cathode terminal connected to the second switching element side.

The phrase “an anode terminal connected to the cathode side of the flash discharge lamp” here refers to a state in which an anode terminal is electrically connected to the cathode of the flash discharge lamp directly or via any circuit element. Similarly, the phrase “a cathode terminal connected to the second switching element side” refers to a state in which a cathode terminal is electrically connected to one terminal of the second switching element directly or via any circuit element. That is, the above configuration illustrates a configuration in which the resistive element and the second diode are connected in series in the path from the cathode of the flash discharge lamp toward the second switching element, and the order of the resistive element and the second diode is intended to be arbitrary as long as the direction in which the current flows does not change.

When the configuration in which one second switching element is connected to the plurality of lighting circuits is adopted, a current flowing from one lighting circuit to the second switching element may flow into another lighting circuit. In general, when current flows in a direction opposite to the assumed direction, an unintended load may be applied to the elements constituting the circuit and cause damage or destruction, which is not preferable.

Therefore, with the above configuration, the flash irradiation apparatus can suppress the current from flowing from one lighting circuit to another lighting circuit by the rectifying action of the second diode.

In the flash irradiation apparatus, the controller may execute the third control after executing the second control, while maintaining the first switching element in the energized state.

As described above, the shimmer current is an extremely weak current generated between the electrodes of the flash discharge lamp, compared to the main discharge, after the trigger voltage is applied to the trigger member and before the main discharge is generated. Even when the shimmer current is stopped after the main discharge is started, the operation of the flash irradiation apparatus is scarcely affected.

That is, with the above configuration, in the flash irradiation apparatus, unnecessary shimmer current is reduced, and current flowing through the resistive element is also reduced. As a result, power consumption in the shimmer resistor is reduced, achieving higher reliability in the flash irradiation apparatus.

According to the present invention, a flash irradiation apparatus suitable for heat treatment in a shorter time is implemented.

### BRIEF DESCRIPTION OF THE DRAWINGS

FIG. 1 is a side view schematically illustrating one embodiment of a flash irradiation apparatus;

FIG. 2 is a circuit diagram illustrating a configuration of a part of a circuit in one embodiment of the flash irradiation apparatus;

FIG. 3 is a circuit diagram illustrating a configuration of a circuit for turning on one flash discharge lamp; and

FIG. 4 is a schematic graph for trigger voltages, control signals, a current, a voltage, and power consumption of a resistive element during two repetitions of main discharge from the start of operation.

### DETAILED DESCRIPTION OF THE PREFERRED EMBODIMENT

Hereinafter, a flash irradiation apparatus according to the present invention will be described with reference to the drawings. Note that each of the drawings described below is schematically illustrated, and dimensional ratios or the numbers of components in the drawings do not necessarily coincide with the actual dimensional ratios or the actual number of components.

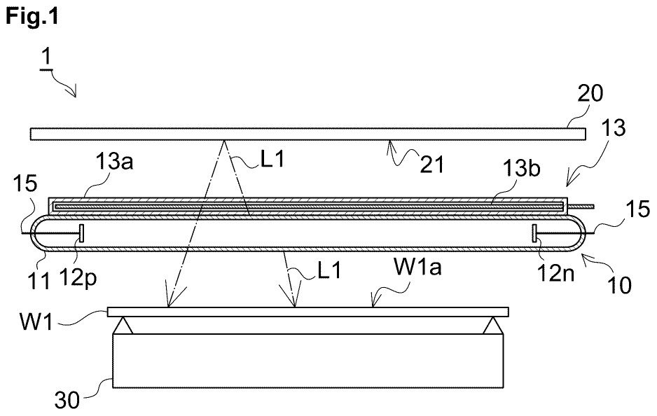

First, a configuration of a flash irradiation apparatus 1 will be described. FIG. 1 is a side view schematically illustrating one embodiment of the flash irradiation apparatus 1. As illustrated in FIG. 1, the flash irradiation apparatus 1 includes a flash discharge lamp 10 and a reflector 20, and is configured to irradiate a main surface W1a of a workpiece W1 supported by a supporter 30 with a flash L1.

Although only one flash discharge lamp 10 is illustrated in FIG. 1, the flash irradiation apparatus 1 may include a plurality of flash discharge lamps 10. As a mere example, a flash irradiation apparatus used for heating treatment of semiconductor wafers is often equipped with about 20 to 30 flash discharge lamps 10.

As illustrated in FIG. 1, the flash discharge lamp 10 in the present embodiment includes a light-emitting tube 11, an anode 12p and a cathode 12n disposed in the light-emitting tube 11 while being separated from each other, and a trigger tube 13 including a tube body 13a and a conductor 13b. When a voltage necessary for light emission is applied between the anode 12p and the cathode 12n via power supply lines (15, 15) and a pulse voltage for triggering is applied to the conductor 13b of the trigger tube 13, discharge occurs in the light-emitting tube 11, and the flash L1 is emitted.

The reflector 20 is disposed on the opposite side of the workpiece W1 as viewed from the flash discharge lamp 10, and has a reflective surface 21 that reflects the flash L1, emitted from the flash discharge lamp 10 and traveling toward the opposite side of the workpiece W1, so as to travel toward the workpiece W1.

In FIG. 1, the trigger tube 13 is disposed on the reflector 20 side as viewed from the light-emitting tube 11. However, the trigger tube 13 may be disposed on the workpiece W1 side as viewed from the light-emitting tube 11.

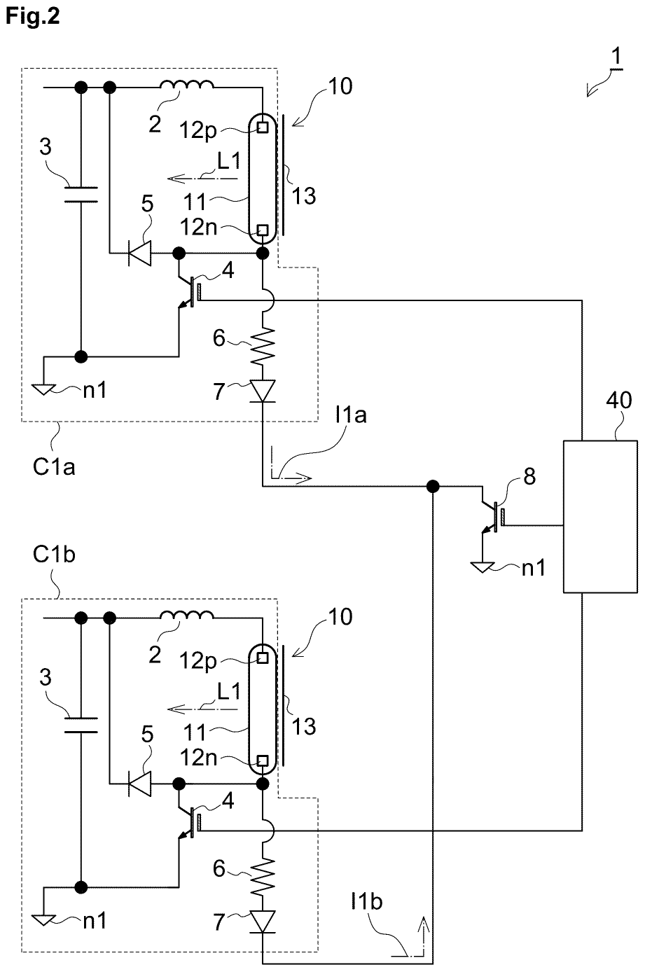

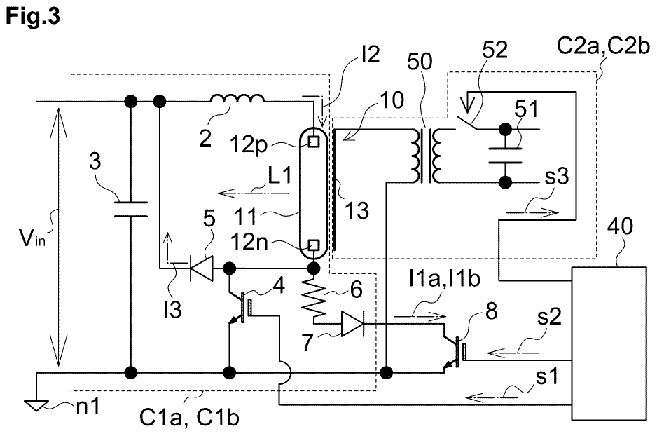

Next, a configuration of a circuit for turning on the flash discharge lamp 10 will be described. FIG. 2 is a circuit diagram illustrating a configuration of a part of a circuit in one embodiment of the flash irradiation apparatus 1, and FIG. 3 is a circuit diagram illustrating a configuration of a circuit for turning on one flash discharge lamp 10. As illustrated in FIG. 2, the flash irradiation apparatus 1 includes a plurality of lighting circuits (C1a, C1b), a second switching element 8, and a controller 40.

In the present embodiment, one terminal of the second switching element 8 and a second terminal of a capacitor 3 in each lighting circuit (C1a, C1b) are connected. However, in FIG. 2, for convenience of illustration, the connection between each terminal is represented by connecting both terminals to a node n1. That is, the node n1 does not represent a node fixed to a predetermined potential by a voltage source or the like.

As illustrated in FIG. 3, a circuit for turning on one flash discharge lamp 10 includes lighting circuits (C1a, C1b) each connected to the anode 12p and the cathode 12n of the flash discharge lamp 10, and a trigger circuit (C2a, C2b) connected to the trigger tube 13.

As illustrated in FIG. 2, each of the lighting circuits (C1a, C1b) includes: an inductor 2 having a first terminal connected to the anode 12p of the flash discharge lamp 10; the capacitor 3 having a first terminal connected to the second terminal of the inductor 2; a first switching element 4 that switches between energization and non-energization of a connection between the cathode 12n of the flash discharge lamp 10 and the second terminal of the capacitor 3; a first diode 5 having a cathode terminal connected to the first terminal of the capacitor 3 and an anode terminal connected to the cathode 12n of the flash discharge lamp 10; and a resistive element 6 having a first terminal connected to the cathode 12n of the flash discharge lamp 10.

Each of the lighting circuits (C1a, C1b) includes a second diode 7 having an anode terminal connected to the second terminal of the resistive element 6 and a cathode terminal connected to one terminal of the second switching element 8. Note that the second diode 7 only needs to be connected in series with the resistive element 6 from the cathode 12n of the flash discharge lamp 10 toward the second switching element 8, and the order of the resistive element 6 and the second diode 7 is arbitrary as long as the direction in which the current (I1a, I1b) flows does not change. When the resistive element 6 is not provided, the peak value of the current (I1a, I1b) is assumed to be on the order of several hundred A to several kA.

Furthermore, a power supply circuit (e.g., a DC-DC converter or the like) for charging the capacitor 3 is connected to a preceding stage of the capacitor 3. However, the description of the power supply circuit is omitted for convenience in describing the configuration of the lighting circuits (C1a, C1b) that contribute to the lighting operation of the flash discharge lamp 10.

In the following description of the operation of the lighting circuit (C1a, C1b), the operation from the state in which charging of the capacitor 3 is completed will be described. The same applies to a trigger capacitor 51 in a trigger circuit (C2a, C2b) described later.

The inductor 2 adjusts a time constant of a current I2 supplied to the flash discharge lamp 10. That is, the inductor 2 adjusts the rising speed and the falling speed of the current I2 supplied from the capacitor 3 to the flash discharge lamp 10. When the adjustment of the time constant of the current I2 by the inductor 2 is unnecessary, or when the time constant of the current I2 can be adjusted by a parasitic inductor element included in a cable or the like connecting the capacitor 3 and the flash discharge lamp 10, the inductor 2 may not be connected.

The capacitor 3 stores electric charge for causing the flash discharge lamp 10 supplied from a power supply or the like to emit light, and operates to discharge the electric charge to the flash discharge lamp 10. In the capacitor 3, electric charge Q (=C×V ᵢₙ) is stored, the electric charge corresponding to a capacitance value C of the capacitor 3 and the output voltage of the power supply circuit (not illustrated) connected to the preceding stage, that is, a voltage Vᵢₙ applied between the terminals of the capacitor 3.

The first switching element 4 is an element that switches a connection between the cathode 12n of the flash discharge lamp 10 and the second terminal of the capacitor 3 between an energized state and a non-energized state. The first switching element 4 in the present embodiment is switched between the energized state and the non-energized state by a control signal s1 (the control signal s1 in the present embodiment is a voltage signal) input from the controller 40 to a control terminal.

Any element can be selected as the first switching element 4 in consideration of current capability, a withstand voltage, a switching speed, an ON resistance, and the like. However, the first switching element 4 in the present embodiment is an insulated gate bipolar transistor (IGBT).

As illustrated in FIG. 3, the first diode 5 is an element that regenerates, via the flash discharge lamp 10, the energy stored in the inductor 2 after the first switching element 4 and the second switching element 8 are switched from the energized state to the non-energized state. Even when the inductor 2 is not connected, regeneration similar to that performed when the inductor 2 is connected is achieved by energy stored in the inductance of the cable connecting the flash discharge lamp 10.

Thus, the current flowing from the anode 12p to the cathode 12n of the flash discharge lamp 10 flows to and is regenerated in the inductor 2 by the first diode 5, so that the first switching element 4 is protected from a high-voltage load. In addition, since the electric charge of the capacitor 3 is not used, a decrease in voltage due to main discharge does not occur.

For this reason, as long as the entire electric charge is not consumed by a leakage current or the like, charging of the capacitor 3 for the next main discharge can be completed in a shorter time and with less energy than charging from a state in which no electric charge is stored.

When the first diode 5 is not provided, the voltage between both terminals of the first switching element 4 may exceed the withstand voltage of the first switching element 4. Protecting the first switching element 4 from a voltage significantly higher than that of a general light-emitting apparatus is particularly important in the flash irradiation apparatus 1 requiring a high light output for performing heating treatment on the workpiece W1.

Although FIGS. 2 and 3 illustrate one first diode 5 in each lighting circuit (C1a, C1b), a diode may be further connected in series to the first diode 5 in each lighting circuit (C1a, C1b). A diode may lose a rectifying action due to deterioration, wear, or the like, resulting in a short circuit between the anode terminal and the cathode terminal.

Therefore, from the viewpoint of fail-safe, a diode having the same rectification direction as the first diode 5 is further connected in series thereto, so as to avoid a short circuit between the first terminal of the capacitor 3 and the cathode 12n of the flash discharge lamp 10 even when one diode element is short-circuited.

The first diode 5 may be, for example, a reverse diode element or the like formed in a semiconductor device as long as the first diode 5 has a rectifying function and is acceptable in terms of withstand voltage and current capability.

The resistive element 6 is an element for maintaining a high resistance value between the cathode 12n of the flash discharge lamp 10 and the second terminal of the capacitor 3, even after a trigger voltage is applied to the trigger tube 13 and the second switching element 8 is switched to the energized state, in order to generate a shimmer discharge, which is a weaker discharge than the main discharge in the light-emitting tube 11. The resistance value of the resistive element 6 is arbitrary. However, an element on the order of several kΩ to several tens kΩ is often adopted so that the flowing current (I1a, I1b) is on the order of several tens mA to several hundreds mA.

However, for the resistive element 6, power consumption, current capability, withstand voltage, and the like need to be considered, and not only a resistance value but also current density can be important factors. As the resistive element 6, any element may be adopted. However, it is assumed that a relatively large resistor is adopted so that the characteristics described above can be satisfied. As a specific example, a resistor having a length on the order of several cm to several tens of cm per side is assumed.

The second diode 7 can prevent, for example, a current (I1a, I1b) flowing from the resistive element 6 toward the second switching element 8 in one lighting circuit C1a from flowing into the other lighting circuit C1b.

Here, when the second diode 7 is not provided, a current I1a from one lighting circuit C1a flows into the other lighting circuit C1b, flows through the resistive element 6 of the lighting circuit C1b, and then flows through the first switching element 4 or the first diode 5 of the lighting circuit C1b.

The flash irradiation apparatus 1 can also be designed so that, even when such a current occurs, the first switching element 4, the first diode 5, and the resistive element 6 can sufficiently withstand the flowing current I1a. When such a design is made, the flash irradiation apparatus 1 may not include the second diode 7.

Although FIGS. 2 and 3 illustrate one second diode 7 in each lighting circuit (C1a, C1b), a diode may be further connected in series to the second diode 7 in each lighting circuit (C1a, C1b). A diode may lose a rectifying action due to deterioration, wear, or the like, resulting in a short circuit between the anode terminal and the cathode terminal.

Therefore, from the viewpoint of fail-safe, a diode having the same rectification direction as the second diode 7 is preferably connected in series thereto, so as to prevent the current I1a from one lighting circuit C1a from flowing into the other lighting circuit C1b even when one diode element is short-circuited.

The second diode 7 may be, for example, a parasitic diode element or the like formed in a semiconductor device as long as the second diode 7 has a rectifying function and is acceptable in terms of withstand voltage and current capability.

The second switching element 8 is an element that switches a connection between the second terminal of the resistive element 6 and the second terminal of the capacitor 3 between the energized state and the non-energized state. The second switching element 8 in the present embodiment is switched between the energized state and the non-energized state by a control signal s2 (the control signal s2 in the present embodiment is a voltage signal) input from the controller 40 to the control terminal.

As the second switching element 8, any element can be selected in consideration of current capability, withstand voltage, switching speed, ON resistance, and the like. However, the second switching element 8 in the present embodiment is an IGBT (Insulated Gate Bipolar Transistor).

As illustrated in FIG. 3, the trigger circuit (C2a, C2b) includes a transformer 50, a trigger capacitor 51 connected in series to the primary side of the transformer 50, and a switching element 52. On the secondary side of the transformer 50, one terminal is connected to the trigger tube 13 of the flash discharge lamp 10, and the other terminal is connected to the second terminal of the capacitor 3.

Note that the trigger circuit C2a and the trigger circuit C2b in the present embodiment have the same circuit configuration, and are denoted by reference numerals so as to correspond to the lighting circuits (C1a, C1b), respectively. That is, the trigger circuit C2a corresponding to the lighting circuit C1a and the trigger circuit C2b corresponding to the lighting circuit C1b are distinguished.

In the trigger circuit (C2a, C2b), when the switching element 52 is switched from the non-energized state to the energized state by a control signal s3 input from the controller 40 in a state where the trigger capacitor 51 is electrically charged, the electric charge stored in the trigger capacitor 51 is discharged, and a current is generated on the primary side of the transformer 50.

By the generation of this current, an electromotive force is generated on the secondary side of the transformer 50, and a pulse voltage is applied to the trigger tube 13 of the flash discharge lamp 10. At this time, when the capacitor 3 of the lighting circuit (C1a, C1b) is charged and the second switching element 8 is controlled to be in the energized state, the pulse voltage applied to the trigger tube 13 triggers a discharge (shimmer discharge) between the anode 12p and the cathode 12n of the flash discharge lamp 10.

As the switching element 52, any element can be selected in consideration of current capability, withstand voltage, switching speed, ON resistance, and the like. However, the switching element 52 in the present embodiment is a thyristor.

The controller 40 is an element that controls the energized and non-energized states of each switching element (4, 8, 52) as described above, and is, for example, an arithmetic processing device such as a central processing unit (CPU) or a micro-processing unit (MPU). Note that the controller 40 may be configured individually for each switching element (4, 8, 52).

Here, the operation of the flash irradiation apparatus 1 from the state in which the capacitor 3 and the trigger capacitor 51 are charged to the end of lighting of the flash discharge lamp 10 will be described.

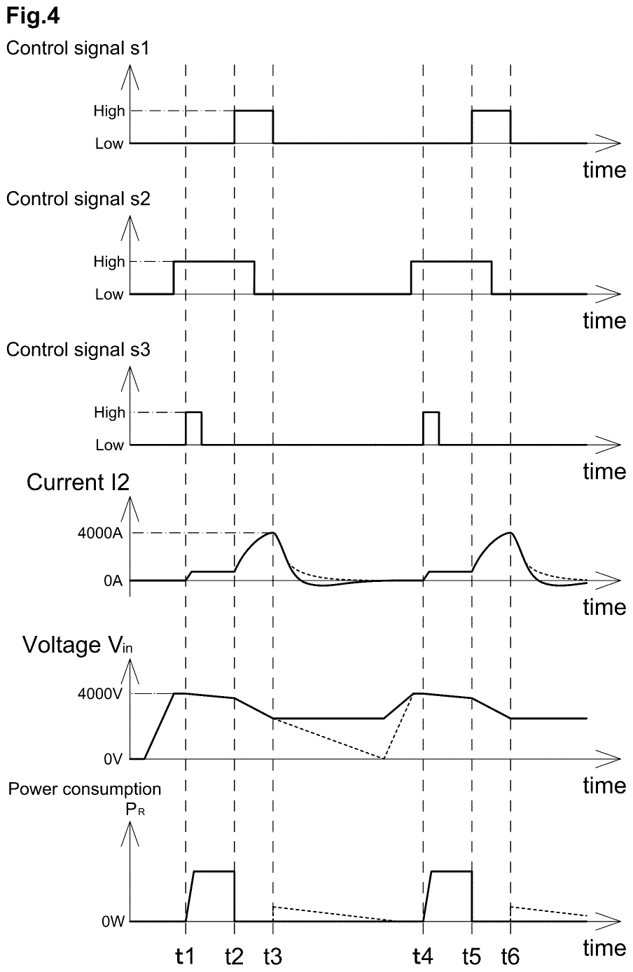

FIG. 4 is a graph for trigger voltages, control signals (s1, s2, s3), the current I2, the voltage Vᵢₙ, and power consumption P_{R} of the resistive element 6 during two repetitions of main discharge from the start of the operation. Note that the power consumption P_{R} of the resistive element 6 is a product of the current (I1a, I1b) and a resistance value R of the resistive element 6. For each of the control signals (s1, s2, s3), the high level corresponds to the control of the switching element (4, 8, 52) in the energized state, and the low level corresponds to the control of the switching element (4, 8, 52) in the non-energized state. As for a part of the graph illustrated in FIG. 4, a graph for a configuration not including the second switching element 8 is shown by a broken line. Hereinafter, the operation of the flash irradiation apparatus 1 will be described with reference to FIGS. 3 and 4.

First, the capacitor 3 and the trigger capacitor 51 are charged. By this operation, as illustrated in FIG. 4, the voltage value of the voltage Vᵢₙ becomes substantially the same as the voltage value of the output voltage of the power supply circuit (not illustrated). In the present embodiment, as an example indicating a guideline, the value of the voltage Vᵢₙ at the time of completion of charging is set to 4000 V.

When the charging of the capacitor 3 and the trigger capacitor 51 is completed, the controller 40 executes control to switch the second switching element 8 from the non-energized state to the energized state. This control corresponds to the first control.

Next, the controller 40 executes control to switch the switching element 52 of the trigger circuit (C2a, C2b) from the non-energized state to the energized state. By this control, an electromotive force is generated on the primary side of the transformer 50, and a trigger voltage is applied to the trigger tube 13. Here, the timing at which the switching element 52 of the trigger circuit (C2a, C2b) is switched from the non-energized state to the energized state is time t1.

When a trigger voltage is applied to the trigger tube 13, a shimmer current flows from the capacitor 3 via the inductor 2, the flash discharge lamp 10, the resistive element 6, and the second switching element 8.

Under the state in which the shimmer current is flowing, the controller 40 executes control to switch the first switching element 4 from the non-energized state to the energized state. This control corresponds to the second control.

By this control, a current flows from the capacitor 3 via the inductor 2, the flash discharge lamp 10, and the first switching element 4, a main discharge occurs, and a flash L1 is emitted. Here, the timing at which the first switching element 4 is switched from the non-energized state to the energized state is time t2.

When the main discharge occurs, there is no need to generate a shimmer current, and thus the controller 40 executes control to switch the second switching element 8 from the energized state to the non-energized state. This control corresponds to the third control.

From the viewpoint of suppressing the electric charge released as the shimmer current and from the viewpoint of reliably generating the main discharge, the control of switching the second switching element 8 from the energized state to the non-energized state is preferably executed before switching of the first switching element 4 from the energized state to the non-energized state. However, the order of these controls may be switched.

Then, at the time of execution of the main discharge necessary for treatment on the workpiece W1 (cf. FIG. 1), the controller 40 executes control to switch the first switching element 4 from the energized state to the non-energized state, and stops the main discharge.

Here, the timing at which the first switching element 4 is switched from the energized state to the non-energized state, that is, at the time of completion of the main discharge, is time t3. In the present embodiment, as an example indicating a guideline, the peak value of the current I2 immediately before the main discharge is stopped is set to 4000 A.

Immediately after the first switching element 4 is switched from the energized state to the non-energized state, both the first switching element 4 and the second switching element 8 are in the non-energized state. However, the current continues to flow through the flash discharge lamp 10 for a while by the energy stored in the inductor 2.

In this manner, a current I3 flows in the forward direction of the first diode 5. As a result, the electric charge flowing to the flash discharge lamp 10 flows to and is regenerated in the inductor 2.

With such a regenerative function, even after the main discharge is completed, electric charge is stored in the capacitor 3, and the voltage Vᵢₙ does not decrease to 0 V.

Furthermore, since no current flows through the resistive element 6 due to the second switching element 8 being in the non-energized state, the voltage Vᵢₙ is maintained at the voltage value after the main discharge is completed, although there is a slight fluctuation caused by the regenerating operation. When the second switching element 8 is not connected and a current (shimmer current) flows through the resistive element 6 even after the main discharge is completed, as indicated by a broken line in the graph of the voltage Vᵢₙ and the graph of the power consumption P_{R} in FIG. 4, the energy remaining in the capacitor 3 is continuously consumed by the resistive element 6, and the voltage Vᵢₙ gradually decreases.

The power consumption P_{R} imposes a load on the resistive element 6 and thus affects the lifespan of the resistive element 6. In addition, the voltage Vᵢₙ affects the amount of energy (electric charge amount) required for charging during the time period (=t4−t3) from the stop of the main discharge to the start of charging for the next main discharge. That is, providing the second switching element 8 and executing the control as described above contributes to extension of the lifespan of the resistive element 6 and to reduction in energy required for the main discharge.

In the flash irradiation apparatus 1 having the above configuration, the current flowing through the flash discharge lamp 10 can be steeply decreased, and the load on the resistive element 6 is suppressed Furthermore, in the flash irradiation apparatus 1 having the above configuration, when the main discharge is repeatedly executed, most of the electric charge remaining in the capacitor 3 at the time of completion of the main discharge can be reused for the next main discharge, thereby further achieving energy saving. By combining such operational effects, the flash irradiation apparatus 1 capable of performing heat treatment on the workpiece W1 in a shorter time is implemented.

The embodiment of the flash irradiation apparatus 1 described above includes the lighting circuits (C1a, C1b) and the trigger circuits (C2a, C2b) provided corresponding to the plurality of flash discharge lamps 10. However, the number and combination of flash discharge lamps 10, lighting circuits (C1a, C1b), and trigger circuits (C2a, C2b) mounted on the flash irradiation apparatus 1 are arbitrary. For example, the flash irradiation apparatus 1 may include one lighting circuit and one trigger circuit for each of the plurality of flash discharge lamps 10, or may include one flash discharge lamp, one lighting circuit, and one trigger circuit.

The configuration of the flash irradiation apparatus 1 described above is merely an example, and the present invention is not limited to each illustrated configuration. That is, for example, any circuit element (e.g., a high-resistance element or a smoothing element) may be connected to each of the lighting circuits (C1a, C1b) and the trigger circuits (C2a, C2b) illustrated in FIG. 2, to the extent that the main circuit operation is not hindered.

What is claimed is:

1. A flash irradiation apparatus comprising:
a flash discharge lamp that generates a flash by discharge;
a lighting circuit including
a capacitor that has a first terminal connected to an anode of the flash discharge lamp and stores electric charge to be supplied to the flash discharge lamp,
a first switching element that switches between energization and non-energization of a connection between a cathode of the flash discharge lamp and a second terminal of the capacitor,
a first diode having a cathode terminal connected to the first terminal of the capacitor and an anode terminal connected to the cathode of the flash discharge lamp, and
a resistive element having a first terminal connected to the cathode of the flash discharge lamp;
a second switching element that switches between energization and non-energization of a connection between the second terminal of the resistive element and the second terminal of the capacitor; and
a controller that controls switching between energization and non-energization of the first switching element and the second switching element,
wherein the controller executes
first control to switch the second switching element from a non-energized state to an energized state,
second control to switch the first switching element from the non-energized state to the energized state after executing the first control, and
third control to switch the second switching element from the energized state to the non-energized state after executing the second control.

2. The flash irradiation apparatus according to claim 1, further comprising a plurality of the lighting circuits,
wherein the second switching element is connected to the plurality of the lighting circuits.

3. The flash irradiation apparatus according to claim 2, wherein each of the plurality of the lighting circuits includes a second diode having an anode terminal connected to a side of the cathode of the flash discharge lamp and a cathode terminal connected to a side of the second switching element.

4. The flash irradiation apparatus according to claim 1, wherein the controller executes the third control after executing the second control, while maintaining the first switching element in the energized state.

5. The flash irradiation apparatus according to claim 2, wherein the controller executes the third control after executing the second control, while maintaining the first switching element in the energized state.

6. The flash irradiation apparatus according to claim 3, wherein the controller executes the third control after executing the second control, while maintaining the first switching element in the energized state.
